(19) United States
(12) Patent Application Publication
(10) Pub. No.: US 2026/0261269 A1
(43) Pub. Date: Sep. 3, 2026

(54) INFORMATION PROCESSING APPARATUS, INFORMATION PROCESSING METHOD, AND NON-TRANSITORY RECORDING MEDIUM

(71) Applicants: Ryo Sato, KANAGAWA (JP); Naoki Asaba, KANAGAWA (JP); Shintaro Kawamura, KANAGAWA (JP)

(72) Inventors: Ryo Sato, KANAGAWA (JP); Naoki Asaba, KANAGAWA (JP); Shintaro Kawamura, KANAGAWA (JP)

(73) Assignee: Ricoh Company, Ltd., Tokyo (JP)

(21) Appl. No.: 19/541,988

(22) Filed: Feb. 17, 2026

(30) Foreign Application Priority Data
Feb. 28, 2025 (JP) 2025-030907
Oct. 22, 2025 (JP) 2025-177966

(51) Int. Cl. H03M 7/30; G06N 3/04

(52) U.S. Cl. CPC H03M 7/3082; G06N 3/04

(57) ABSTRACT

An information processing apparatus includes circuitry to transform non-text information into vectorized information using an information vectorizing model, transform the vectorized information into a first output in a first format processable by a first large-scale language model, transform the first output into a second output in a second format processable by a second large-scale language model, input the second output to the second large-scale language model, and output a response based on a processing result of the second large-scale language model. The second format is different from the first format.

### CROSS-REFERENCE TO RELATED APPLICATIONS

This patent application is based on and claims priority pursuant to 35 U.S.C. §119(a) to Japanese Patent Application Nos. 2025-030907, filed on February 28, 2025, and 2025-177966, filed on October 22, 2025, in the Japan Patent Office, the entire disclosure of which is hereby incorporated by reference herein.

### BACKGROUND

### Technical Field

The present disclosure relates to an information processing apparatus, an information processing method, and a non-transitory recording medium.

### Related Art

A technique of encoding an image with an image encoder and processing the encoded image with a text encoder has been proposed.

A model that transforms non-text information into vectors, such as a vision encoder (a model for image vectorization), can be integrated with a large-scale language model (LLM) through an adapter layer. In this architecture, the adapter layer transforms the output vectors from the non-text model, which vectorizes non-text information, into a format that the LLM can process. A system employing this approach is referred to as a large multimodal model (LMM).

In such an LMM, when the combination of the model that vectorizes non-text information with the LLM is changed, a new adapter layer to accommodate the new combination of the model that vectorizes non-text information with the LLM is used.

### SUMMARY

The present disclosure described herein provides an information processing apparatus including circuitry to transform non-text information into vectorized information using an information vectorizing model, transform the vectorized information into a first output in a first format processable by a first large-scale language model, transform the first output into a second output in a second format processable by a second large-scale language model, input the second output to the second large-scale language model, and output a response based on a processing result of the second large-scale language model. The second format is different from the first format.

The present disclosure described herein provides an information processing method including transforming non-text information into vectorized information using an information vectorizing model, transforming the vectorized information into a first output in a first format processable by a first large-scale language model, transforming the first output into a second output in a second format processable by a second large-scale language model, inputting the second output to the second large-scale language model, and outputting a response based on a processing result of the second large-scale language model. The second format is different from the first format.

The present disclosure described herein provides a non-transitory recording medium storing a plurality of program codes which, when executed by one or more processors, causes the one or more processors to perform a method. The method includes transforming non-text information into vectorized information using an information vectorizing model, transforming the vectorized information into a first output in a first format processable by a first large-scale language model, transforming the first output into a second output in a second format processable by a second large-scale language model, inputting the second output to the second large-scale language model, and outputting a response based on a processing result of the second large-scale language model. The second format is different from the first format.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a diagram illustrating a configuration of an information processing system;

FIG. 2 is a schematic block diagram illustrating a hardware configuration of a server or a personal computer;

FIG. 3 is a block diagram illustrating a functional configuration of a server;

FIG. 4 is a conceptual diagram of a transformation process performed by a server;

FIG. 5 is a conceptual diagram of a method for generating a text vector by a first LLM and a second LLM illustrated in FIG. 3;

FIG. 6 is a diagram of vector spaces generated by the first LLM and the second LLM illustrated in FIG. 3, respectively;

FIG. 7 is a diagram illustrating a method performed by the server illustrated in FIG. 3, for obtaining the transformation relation of word vectors between the first LLM and the second LLM;

FIG. 8 is a diagram illustrating the relation among an image vector, a token vector space, and a transformation layer;

FIG. 9 is a diagram illustrating a method for generating a transformation layer by a transformation layer generation unit of the server illustrated in FIG. 3;

FIG. 10 is a conceptual diagram illustrating the comparison between a method for coping with the change of an LLM according to an embodiment of the present disclosure and a comparative method;

FIG. 11 is a block diagram illustrating a functional configuration of a server and a personal computer (PC);

FIG. 12 is a diagram illustrating a data table stored in a storage unit of a server;

FIG. 13 is a flowchart of a generative artificial intelligence (AI) chat process by the server and the PC illustrated in FIG. 11;

FIG. 14 is a diagram of a generative AI chat screen displayed on a PC;

FIG. 15 is another diagram of a generative AI chat screen displayed on a PC; and

FIG. 16 is another diagram of a generative AI chat screen displayed on a PC.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

### Configuration of Information Processing System 10

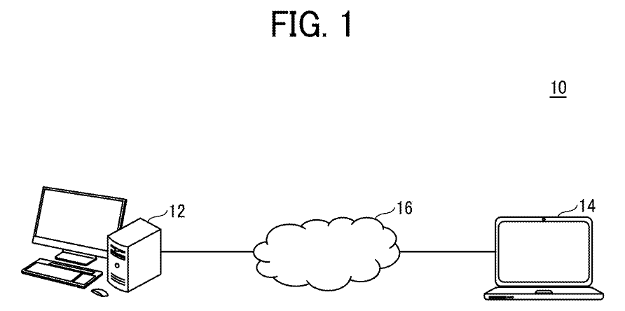

FIG. 1 is a diagram illustrating a configuration of an information processing system 10.

The information processing system 10 illustrated in FIG. 1 includes a server 12 and a personal computer (PC) 14. The server 12 and the PC 14 are connected to communicate with each other through a communication network 16. The communication network 16 is, for example, a local area network (LAN) or the Internet.

The PC 14 is an example of a terminal device. The PC 14 includes an input device to input text (a character string) and non-text information. Examples of the input device include a keyboard and a touch screen. The PC 14 can transmit the text and the non-text information input by the user using the input device to the server 12 through the communication network 16. The PC 14 may have a speech recognition function of recognizing voice input by the user using a microphone. In this case, the PC 14 may transmit the text recognized by the speech recognition function to the server 12.

The server 12 is an example of an information processing apparatus. The server 12 receives the text and the non-text information transmitted from the PC 14 via the communication network 16, and performs predetermined processing (for example, text segmentation or prediction) by the LLM, thereby generating text data corresponding to the received text and non-text information. At this time, the server 12 transforms non-text information into a format processable by the LLM using a model to vectorize the non-text information and the adapter layer. The adapter layer is a layer that transforms an output of a model that vectorizes non-text information into a format that can be input to the LLM. For example, when the non-text information is an image, the data is transformed into a format processable by the LLM using a vision encoder and an adapter layer. The server 12 outputs the text data as the result of the processing performed by the LLM to the PC 14 via the communication network 16.

In other words, the server 12 functions as a large multimodal model (LMM). AN LMM is a model that processes text and non-text information, such as an image, as inputs in parallel and generates sentences. The LMM includes a model that vectorizes non-text information (may be referred to as a submodel or a module), an LLM, and an adapter layer. The LMM may have a model to vectorize pieces of non-text information. In the description below, the data transmitted from the PC 14 and the non-text information processed by the LMM are images, but the data are not limited to images. For example, the data may include sounds. In the description below, the LMM includes a vision encoder, an LLM, and an adapter layer. The vision encoder vectorizes images. The adapter layer transforms the image vector output from the vision encoder into a format (that is, a new image vector) that can be processed by the LLM. Specifically, the adapter layer adjusts the dimensionality of the image vector output from the vision encoder to match the dimensionality of the vector of the text processed by the LLM. The LLM performs the predetermined processing (for example, text segmentation or prediction) on the new image vector output from the adapter layer, to generate text data corresponding to the input image and text.

The PC 14 receives the text transmitted from the server 12 (that is, the text obtained as a result of the processing by the LLM) via the communication network 16 and performs various types of processing (for example, screen display) using the text.

In the configuration illustrated in FIG. 1, one terminal device (the PC 14) is connected to the server 12 through the communication network 16. However, in actuality, the information processing system 10 allows multiple terminal devices to connect to the server 12 through the communication network 16, and images and text can be transmitted to the server 12 from each of the terminal devices.

In the configuration illustrated in FIG. 1, the PC 14 is an example of the terminal device to input images and text. However, the terminal device is not limited thereto, and may be any device (e.g., a smartphone, a tablet terminal, an electronic whiteboard, an inkjet printer, a multifunction peripheral (MFP), a video conference terminal, a projector, or a spherical imaging device) that can at least input and transmit images and text.

### Hardware Configuration of Server 12 and PC 14

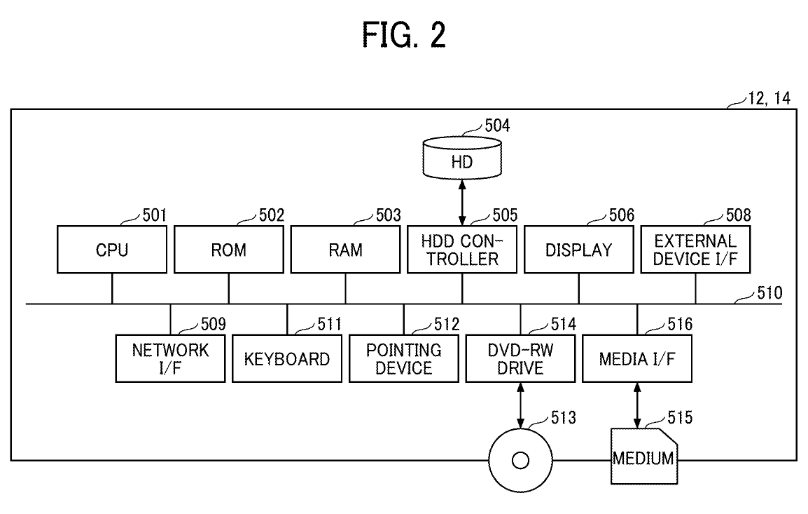

FIG. 2 is a block diagram illustrating a hardware configuration applicable to the server 12 and the PC 14. A hardware configuration common to the server 12 and the PC 14 is described below.

As illustrated in FIG. 2, each of the server 12 and the PC 14 is implemented by a computer. The computer includes a central processing unit (CPU) 501, a read-only memory (ROM) 502, a random-access memory (RAM) 503, a hard disk (HD) 504, a hard disk drive (HDD) controller 505, a display 506, an external device interface (I/F) 508, a network I/F 509, a data bus 510, a keyboard 511, a pointing device 512, a digital versatile disk-rewritable (DVD-RW) drive 514, and a media I/F 516.

The CPU 501 controls the entire operation of the server 12 or the PC 14. The ROM 502 stores programs, such as an initial program loader (IPL), for driving the CPU 501. The RAM 503 is used as a work area for the CPU 501. The HD 504 is a storage area that stores various data such as a program. The HDD controller 505 controls an HDD to read or write various kinds of data from or to the HD 504 under the control of the CPU 501. The display 506 displays various kinds of information such as a cursor, a menu, a window, characters, or an image. The external device I/F 508 is an interface for connecting to various external devices. Examples of the external device include, but are not limited to, a universal serial bus (USB) memory and a printer. The network I/F 509 is an interface for data communication via the communication network 16. The data bus 510 is, for example, an address bus or a data bus that electrically connects components such as the CPU 501 illustrated in FIG. 2.

The keyboard 511 is a kind of input device including keys used to input a character, a numerical value, and various instructions. The pointing device 512 is an example of an input device that allows a user to select or execute various instructions, select a target to be processed, or move a cursor being displayed. The DVD-RW drive 514 reads and writes various data from and to a DVD-RW 513, which is an example of a removable recording medium. The removable recording medium is not limited to a DVD-RW and may be a digital versatile disc-recordable (DVD-R) or the like. The media I/F 516 controls the reading or writing (storing) of data from or to a medium 515 (storage medium), such as a flash memory.

### Functional Configuration of Server 12

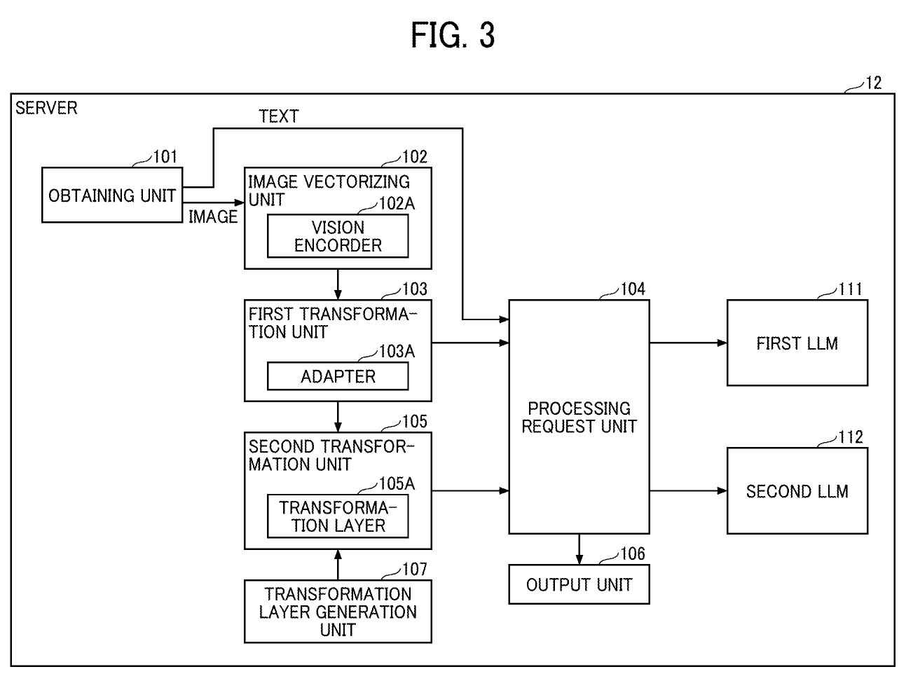

FIG. 3 is a block diagram illustrating a functional configuration of the server 12. FIG. 3 illustrates multiple functions related to the process of generating text corresponding to input images and text by a first LLM 111 and a second LLM 112 among the functions included in the server 12.

As illustrated in FIG. 3, the server 12 includes an obtaining unit 101, an image vectorizing unit 102 (an example of an information vectorizing unit), a first transformation unit 103, a processing request unit 104, a second transformation unit 105, an output unit 106, a transformation layer generation unit 107, a first LLM 111 (an example of a first large-scale language model), and a second LLM 112 (an example of a second large-scale language model).

The obtaining unit 101 obtains images and texts from the PC 14 via the communication network 16. The image obtained by the obtaining unit 101 is output to the image vectorizing unit 102. The text obtained by the obtaining unit 101 is output to the processing request unit 104.

The image vectorizing unit 102 vectorizes, using a vision encoder 102A, the image obtained by the obtaining unit 101. The vision encoder 102A is an example of an information vectorizing model that transforms non-text information into a vector (vectorized information) and outputs the vector, and an example of an image vectorizing model that transforms an image into a vector and outputs the vector. The image vectorizing model is a model to vectorize an input image. In other words, when an image is input, the image vectorizing model outputs a vector corresponding to the image.

The first transformation unit 103 transforms the output of the image vectorizing unit 102 into a first output in a first format processable by the first LLM 111 using an adapter 103A (adapter layer) corresponding to the combination of the vision encoder 102A and the first LLM 111.

The processing request unit 104 outputs the text obtained by the obtaining unit 101 and the output of the first transformation unit 103 to the first LLM 111, thereby requesting the first LLM 111 to execute the predetermined processing (for example, text segmentation or prediction). Then, the processing request unit 104 obtains, from the first LLM 111, the text corresponding to the image and text obtained by the obtaining unit 101 as a result of the predetermined processing.

When the output destination of the processing request unit 104 is switched to the second LLM 112, the second transformation unit 105 transforms the first output of the first transformation unit 103 into a second output in a second format processable by the second LLM 112, using a transformation layer 105A. In this case, the processing request unit 104 outputs the text obtained by the obtaining unit 101 and the output of the second transformation unit 105 to the second LLM 112, thereby requesting the second LLM 112 to execute the predetermined processing (for example, text segmentation or prediction). The processing request unit 104 then obtains, from the second LLM 112, the text corresponding to the image and text obtained by the obtaining unit 101 as a result of the predetermined processing.

In particular, the second transformation unit 105 transforms, by linear transformation, the output of the first transformation unit 103 into a format processable by the second LLM 112 (that is, a further new image vector) using the transformation layer 105A.

The output unit 106 obtains the result of the predetermined processing by the first LLM 111 or the second LLM 112 (for example, the text corresponding to the images and text obtained by the obtaining unit 101) from the processing request unit 104, and outputs a response based on the processing result to the PC 14 via the communication network 16. The response may be generated by editing and correcting the output of the LLM or the output of the LLM as it is. The response is not limited to text, and may be voice or an image.

The transformation layer generation unit 107 generates the transformation layer 105A to transform the output of the first transformation unit 103 into a format processable by the second LLM 112.

The first LLM 111 and the second LLM 112 execute predetermined processing (for example, text segmentation or prediction) in response to a processing request from the processing request unit 104.

For example, the first LLM 111 and the second LLM 112 segment the image and the text into vocabularies (that is, morphemes) by text segmentation. In particular, the first LLM 111 and the second LLM 112 each have a tokenizer. The tokenizer includes a vocabulary group. The vocabulary group includes multiple vocabularies associated with identifiers. The vocabulary group is implemented by, for example, a JavaScript Object Notation (JSON) file. The tokenizer performs text segmentation (i.e., tokenization processing) using an existing technique on the image and text output from the processing request unit 104 based on the vocabulary group, to segment the image and text into multiple vocabularies (i.e., multiple morphemes).

For example, the first LLM 111 and the second LLM 112 perform prediction processing on the result of the text segmentation (that is, multiple vocabularies), to generate text corresponding to the image and text obtained by the obtaining unit 101. The first LLM 111 and the second LLM 112 then output the text generated by the prediction processing to the processing request unit 104.

Each of the functions of the above-described embodiments may be implemented by one or more pieces of processing circuitry. The “processing circuit or circuitry” in the present specification includes a programmed processor to execute each function by software, such as a processor implemented by an electronic circuit, and devices, such as an application-specific integrated circuit (ASIC), a digital signal processor (DSP), a field-programmable gate array (FPGA), and circuit modules arranged to perform the recited functions.

### Transformation Process by Server 12

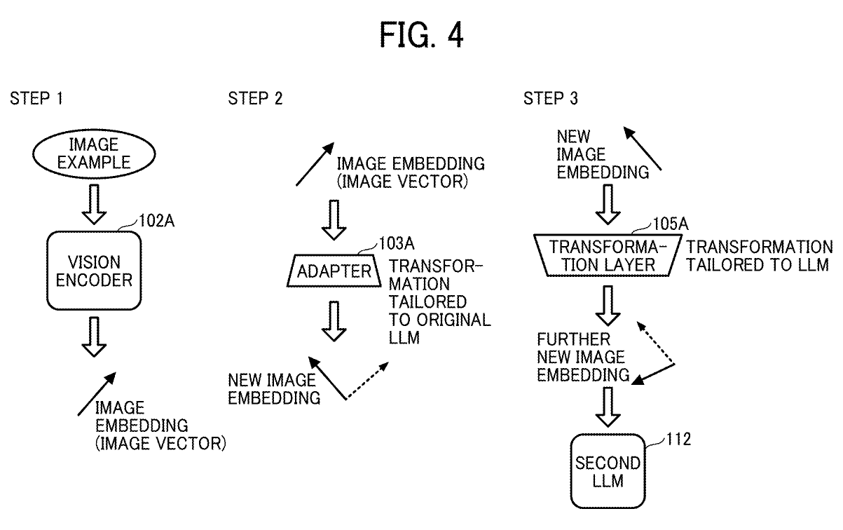

FIG. 4 is a conceptual diagram of a transformation process performed by the server 12. As illustrated in FIG. 4, the server 12 executes Step 1, Step 2, and Step 3 in this order as the transformation process. FIG. 4 illustrates the transformation process executed by the server 12 after the LLM that performs the predetermined process (for example, text segmentation or prediction) is switched to the second LLM 112. FIG. 4 illustrates a transformation process for an image obtained from the PC 14.

In Step 1, the obtaining unit 101 obtains an image from the PC 14 (obtaining step). Then, the image vectorizing unit 102 vectorizes the image obtained by the obtaining unit 101 using the vision encoder 102A (image vectorization step).

In Step 2, the first transformation unit 103 transforms the output (the image vectors or vectorized information) of the image vectorizing unit 102 into a format processable by the first LLM 111 (that is, new image vectors) using the adapter 103A corresponding to the combination of the vision encoder 102A and the first LLM 111 (first transformation step).

In Step 3, the second transformation unit 105 transforms the output of the first transformation unit 103 (that is, new image vectors) into a format processable by the second LLM 112 (that is, further new image vectors) using the transformation layer 105A (second transformation step). In particular, the second transformation unit 105 transforms, by linear transformation, the output of the first transformation unit 103 (that is, the new image vectors) into a format (that is, further new image vectors) processable by the second LLM 112 using the transformation layer 105A.

The processing request unit 104 then outputs the output of the second transformation unit 105 (that is, the further new image vectors) to the second LLM 112, thereby requesting the second LLM 112 to execute the predetermined processing (for example, text segmentation or prediction), which is a processing request step.

As described above, the server 12 transforms the output of the first transformation unit 103 into a format processable by the second LLM 112 by the second transformation unit 105 using the transformation layer 105A.

Accordingly, even when the LLM in the LMM is changed to the second LLM 112, the server 12 can transform the image vectors output from the vision encoder 102A (image vectorizing unit) into a format processable in the second LLM 112, only by adding the transformation layer 105A to the adapter 103A, without generating a new adapter.

### Method for Generating Text Vector by LLM

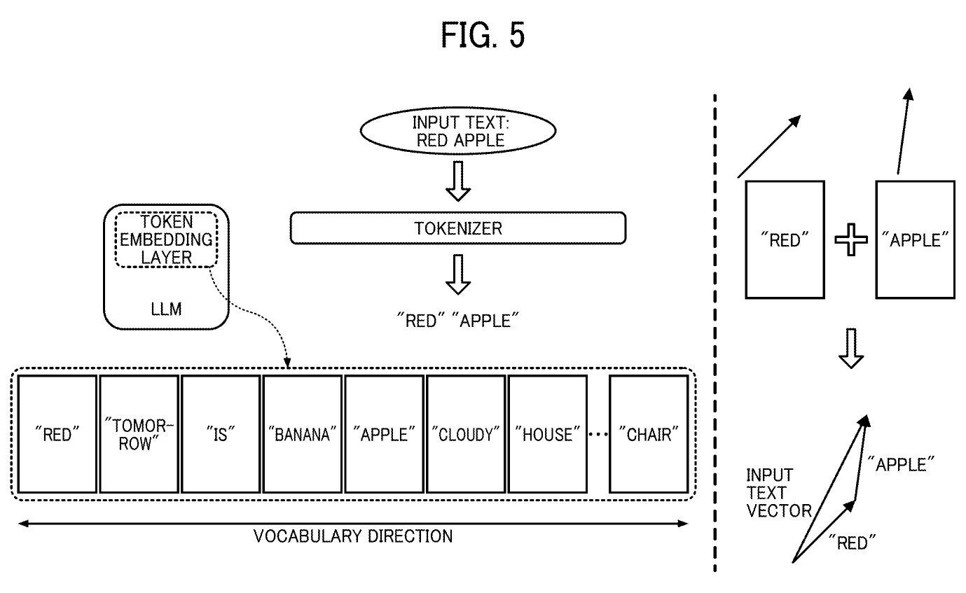

FIG. 5 is a conceptual diagram of a method for generating a text vector by the first LLM 111 and the second LLM 112. A method for generating a text vector common to the first LLM 111 and the second LLM 112 will be described below.

As illustrated in FIG. 5, the LLM includes a token embedding layer and a tokenizer. The token embedding layer stores vectors individually corresponding to the respective identifiers of the vocabularies included in the LLM.

The tokenizer decomposes an input text into multiple tokens (vocabularies), and outputs each of the tokens in association with the identifier indicating the vocabulary. The token embedding layer outputs a vector corresponding to the identifier output from the tokenizer. Thus, the LLM obtains the vector representation of the input text by using the token embedding layer and the tokenizer.

For example, in the example illustrated in FIG. 5, the tokenizer breaks down the input text “red apple” into the token “red” and the token “apple” as illustrated in the left column of FIG. 5.

As illustrated in the right column of FIG. 5, the tokenizer obtains the vector of the token “red” and the vector of the token “apple” from the token embedding layer.

Further, as illustrated in the right column of FIG. 5, the tokenizer sums the vector of the token “red” and the vector of the token “apple” and divides the sum by 2, thereby obtaining a vector representation (word vector or token vector) for the input text “red apple.” The right column of FIG. 5 presents the vectors before division by 2.

### Vector Space Generated by LLM

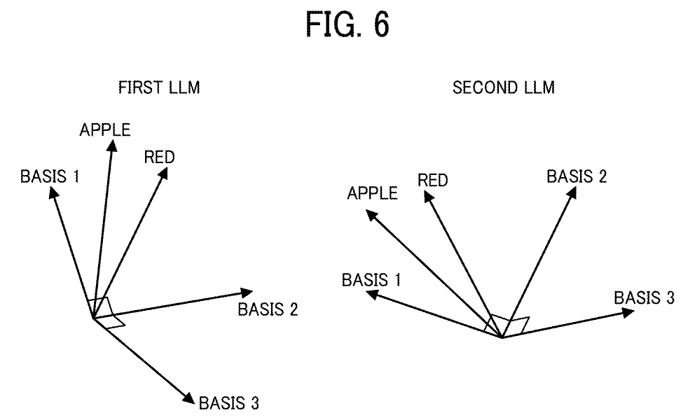

FIG. 6 is a diagram of vector spaces generated by the first LLM 111 and the second LLM 112, respectively.

As illustrated in FIG. 6, the vector spaces generated by the token embedding layer are different between the first LLM 111 and the second LLM 112. For example, in the configuration illustrated in FIG. 6, the directions of the three bases (basis 1, basis 2, and basis 3) of the vector space are different between the first LLM 111 and the second LLM 112. Accordingly, in FIG. 6, the direction of the vector of the token “red” and the direction of the vector of the token “apple” are different between the first LLM 111 and the second LLM 112. The basis is a set of vectors serving as axes defining a vector space, and a vector in the vector space can be represented by a linear combination of vectors indicating the basis.

However, if the LLM is ideally learned, the vector relationship between two tokens is considered to be constant regardless of the combination of two tokens, and thus can be represented by a constant linear transformation relation.

Based on this, the inventors have found that linearly transforming the word vectors by the transformation layer 105A of the second transformation unit 105 allows the word vectors processable in the first LLM 111 before the change (that is, the output of the first transformation unit 103) to be transformed into the word vectors processable in the second LLM 112 after the change.

### Method for Obtaining transformation relation of Word Vectors between Two LLMs

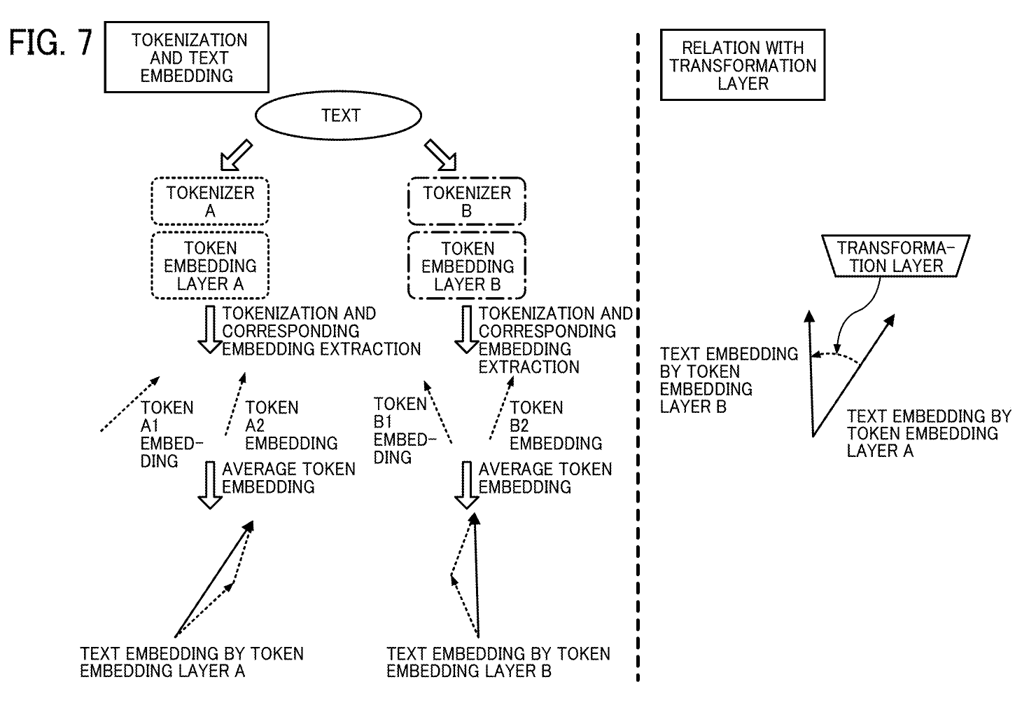

FIG. 7 is a diagram illustrating a method for obtaining a transformation relation of word vectors between the first LLM 111 and the second LLM 112 by the server 12.

First, as illustrated in the left column of FIG. 7, the server 12 inputs an identical text to the first LLM 111 and the second LLM 112, and generates a word vector in each of the first LLM 111 and the second LLM 112 by the tokenizer and the token embedding layer.

Then, as illustrated in the right column of FIG. 7, the server 12 derives a transformation relation between the word vector generated by the first LLM 111 and the word vector generated by the second LLM 112 by a predetermined calculation process. As the transformation relation, a linear transformation matrix is derived.

The server 12 repeatedly executes the generation of the word vector and the calculation of the transformation relation described above until the loss of the transformation relation (linear transformation matrix) converges while changing the text input to the first LLM 111 and the second LLM 112. The server 12 may calculate the convergence of the loss by an existing method, such as a steepest descent method.

Then, when the loss of the transformation relation (linear transformation matrix) converges in the above repeated processing, the server 12 ends the process, and determines the transformation relation (linear transformation matrix) obtained last as a formal transformation relation (linear transformation matrix).

### Relationship among Image Vector, Token Vector Space, and Transformation Layer

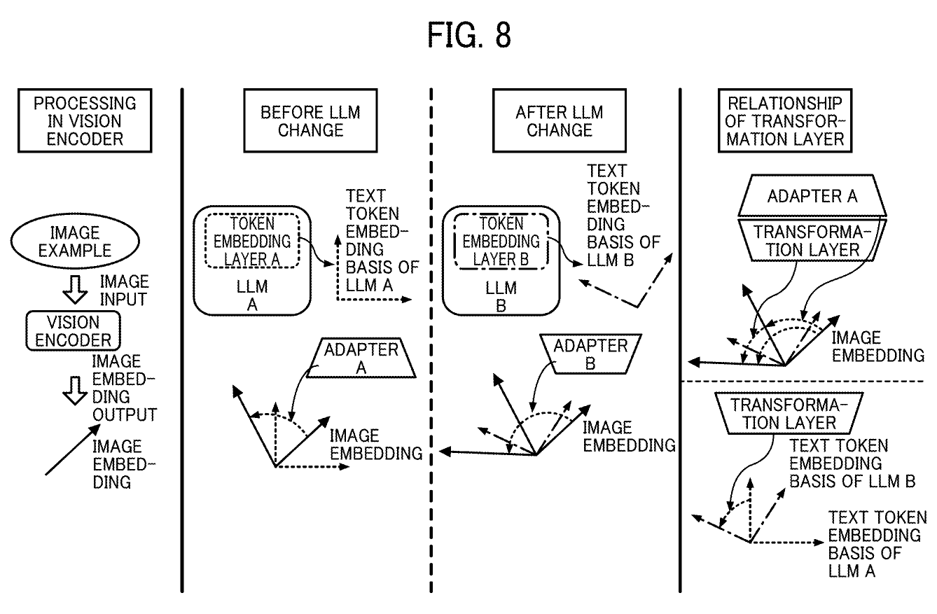

FIG. 8 is a diagram illustrating the relationship among an image vector, a token vector space, and a transformation layer. As illustrated in the first column from the left of FIG. 8, the image vector output from the vision encoder is adjusted in the direction of the first LLM 111 (LLM A in FIG. 8), and is represented in the token vector space generated by the token embedding layer of the first LLM 111 through an adapter A (adapter 103A).

However, the adapter A corresponds to the combination of the vision encoder and the first LLM 111. In the related art, when the large-scale language model to be used is switched from the first LLM 111 to the second LLM 112 (LLM B in the figure), a new Adapter B is generated to cope with the combination of the vision encoder and the second LLM 112, which costs a lot.

In view of this, the server 12 according to the present embodiment generates a transformation layer (transformation layer 105A) between the adapter A and the second LLM 112, as illustrated in the first column from the right in FIG. 8. The transformation layer 105A obviates generating the new adapter B and transforms the output of the adapter A into a format processable by the second LLM 112. The transformation relation by the transformation layer 105A is computed by the method illustrated in FIG. 7 based on the geometric relation of the vector space. The transformation layer 105A performs linear transformation representing a basis relation between the token embedding layer A included in the first LLM 111 and the token embedding layer B included in the second LLM 112.

### Method for Generating Transformation Layer 105A

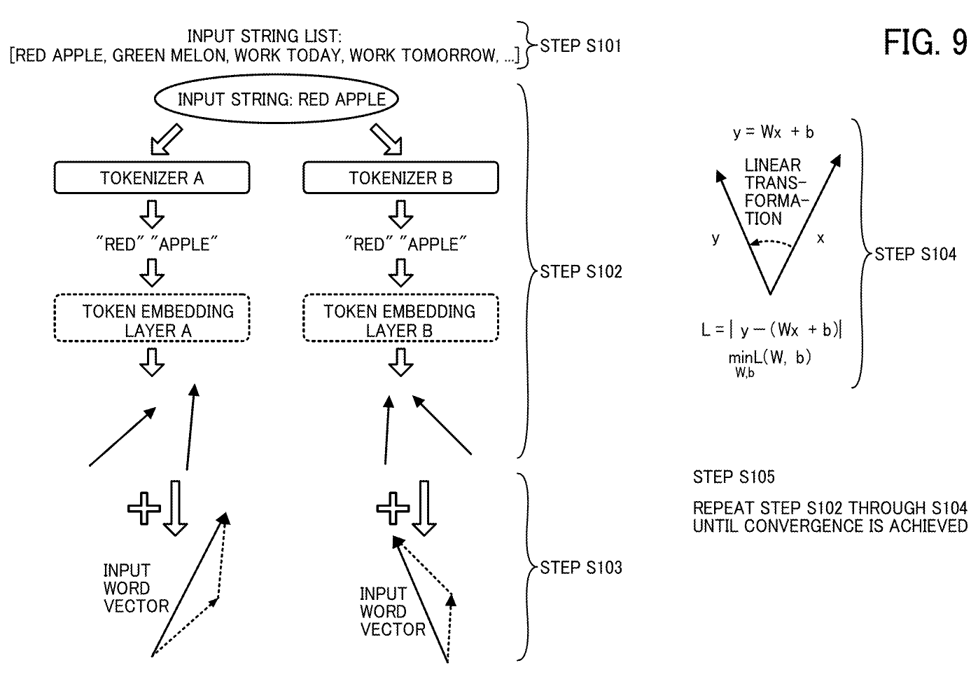

FIG. 9 is a diagram illustrating a method for generating the transformation layer 105A by the transformation layer generation unit 107 of the server 12.

In FIG. 9, the first LLM 111 includes the token embedding layer A and a tokenizer A. The second LLM 112 includes the token embedding layer B and a tokenizer B.

The token embedding layer A and the tokenizer A are examples of a “first text vectorizing model.” The token embedding layer B and the tokenizer B are examples of a “second text vectorizing model.” A text vectorizing model is a model that outputs a vector corresponding to an input text (string).

In step S101, the transformation layer generation unit 107 prepares multiple texts (strings).

In step S102, the transformation layer generation unit 107 inputs a single common string (red apple) selected from the strings prepared in step S101 to each of the first LLM 111 and the second LLM 112, thereby causing each of the first LLM 111 and the second LLM 112 to divide the single string into two vocabularies, to generate the token vectors of the two vocabularies.

At this time, in the first LLM 111, the tokenizer B divides one string into two vocabularies.

The token embedding layer B then generates the token vectors of the two vocabularies.

In the second LLM 112, the tokenizer A divides one string into two vocabularies. The token embedding layer A then generates the token vectors of the two vocabularies.

In step S103, the transformation layer generation unit 107 causes each of the first LLM 111 and the second LLM 112 to generate a word vector from the token vectors of the two vocabularies generated by step S102. Specifically, each of the first LLM 111 and the second LLM 112 generates a word vector by averaging the token vectors of the two vocabularies.

In step S104, the transformation layer generation unit 107 obtains the transformation relation (linear transformation matrix) between the word vector (an example of a “first word vector”) generated by the first LLM 111 and the word vector (an example of a “second word vector”) generated by the second LLM 112 by a predetermined calculation process. For example, the transformation layer generation unit 107 obtains a linear deformation matrix in which the absolute value (loss) of the difference between the vector obtained by linearly transforming the first word vector and the second word vector is minimized.

In step S105, the transformation layer generation unit 107 repeatedly executes step S102 to step S104 until the loss of the transformation relation (linear transformation matrix) calculated by step S104 converges while changing the common string input to the first LLM 111 and the second LLM 112.

When the loss of the transformation relation (linear transformation matrix) converges in the above step S105, the transformation layer generation unit 107 ends the process illustrated in FIG. 9, and determines the transformation relation (linear transformation matrix), represented as “W” and “b” in the expression illustrated in FIG. 9, obtained last as the transformation layer 105A.

The transformation layer 105A generated by the transformation layer generation unit 107 is used by the second transformation unit 105 to transform the output of the first transformation unit 103 into a format processable by the second LLM 112.

As described above, in the server 12, the second transformation unit 105 linearly transforms the output of the first transformation unit 103 using the transformation layer 105A, thereby transforming the output into a format processable by the second LLM 112.

Thus, the server 12 linearly transforms the output of the first transformation unit 103 using the transformation layer 105A, without changing the adapter 103A of the first transformation unit 103. This achieves the transformation of the output of the first transformation unit 103 into a format processable by the second LLM 112 by relatively simple computing.

Further, in the server 12, the transformation layer generation unit 107 generates the transformation layer 105A based on the relation between the basis of the first vector obtained by the first text vectorizing model (included in the first LLM 111) to vectorize text and the basis of the second vector obtained by the second text vectorizing model (included in the second LLM 112) to vectorize text.

Accordingly, the server 12 can generate the transformation layer 105A to absorb the difference between the basis of the first vector and the basis of the second vector with high accuracy by the linear transformation.

In particular, the transformation layer generation unit 107 of the server 12 generates a first word vector by averaging multiple vectors obtained by inputting a string to the first LLM 111, generates a second word vector by averaging multiple vectors obtained by inputting the string to the second LLM 112, and generates the transformation layer 105A that linearly transforms the first word vector into the second word vector, based on the first word vector and the second word vector.

In this manner, the server 12 generates the transformation layer 105A that absorbs the difference between the first word vector and the second word vector with high accuracy by linear transformation.

The transformation layer generation unit 107 may generate the transformation layer 105A by a method other than the method based on the first word vector and the second word vector.

The transformation layer generation unit 107 may generate the transformation layer 105A by a method other than the method concerning the basis of the first vector and the basis of the second vector.

The transformation layer 105A is not limited to a layer that linearly transforms the output of the first transformation unit 103.

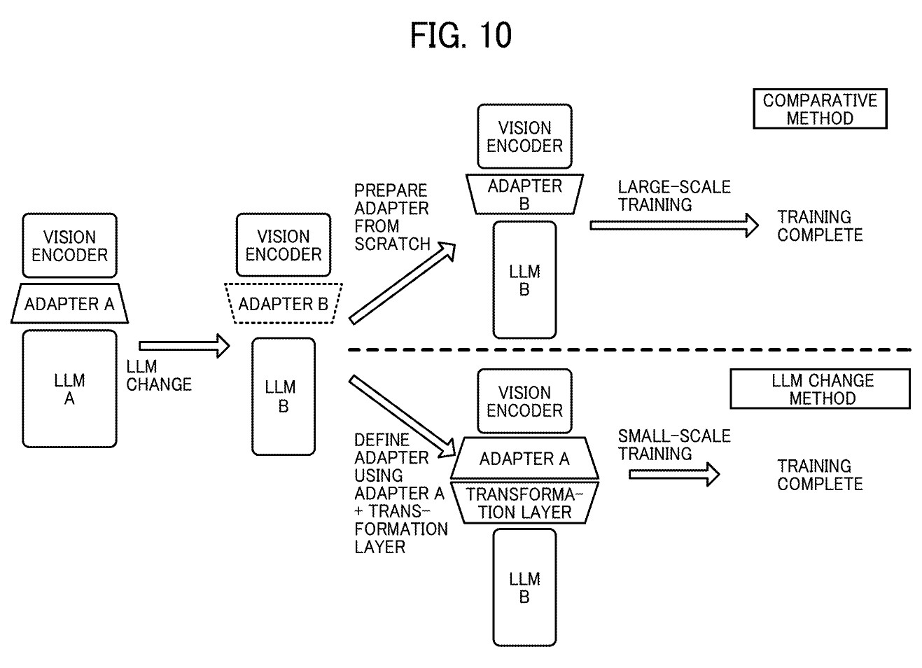

FIG. 10 is a conceptual diagram illustrating the method according to the present embodiment and a comparative method. FIG. 10 illustrates an example in which the LLM that performs the predetermined process (for example, text segmentation or prediction) is changed from “LLM A” to “LLM B.”

As illustrated in FIG. 10, in the comparative method, when the LLM that performs the predetermined process is changed from “LLM A” to “LLM B,” it is necessary to newly generate an “adapter B” corresponding to the combination of the vision encoder and “LLM B” instead of the “adapter A” corresponding to the combination of the vision encoder and “LLM A.”

In the comparative method, extensive training on the newly generated “adapter B” is required to tailor the newly generated adapter B to “LLM B.”

By contrast, as illustrated in FIG. 10, in the method according to the present embodiment, when the LLM that performs the predetermined process is changed to “LLM B,” the “adapter A” corresponding to “LLM A” is used as it is, and a transformation layer for transforming the output of “adapter A” into a format usable for “LLM B” is added. At this time, in the method according to the present embodiment, since the “adapter A” has already been trained, only a small amount of training is performed on the transformation layer so as to adapt to the “LLM B.”

### Operational Examples

A generative artificial intelligence (AI) chat using the transformation layer generated by the transformation layer generation unit 107 will be described below.

### Functional Configuration of Server 12 and PC 14

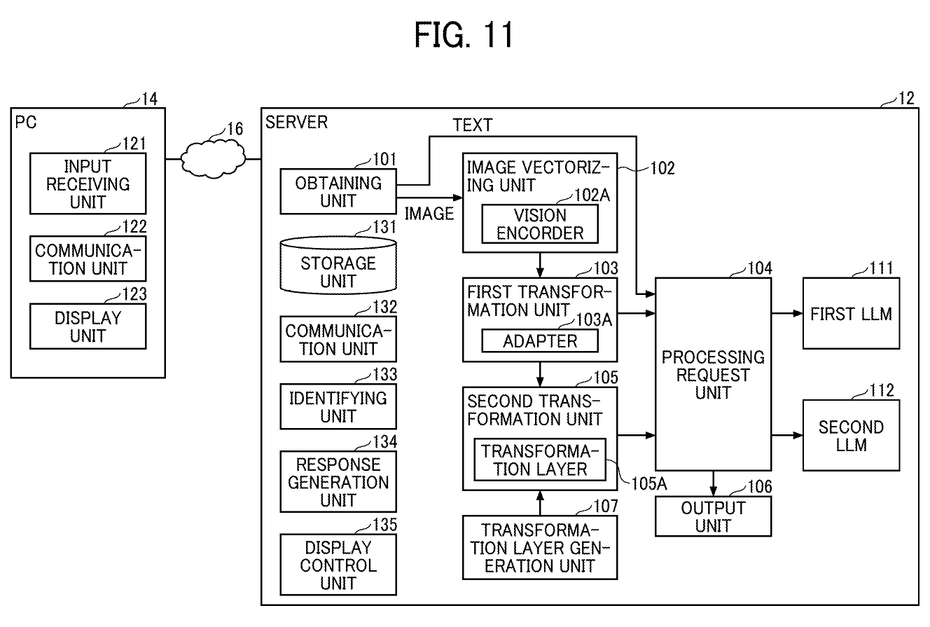

FIG. 11 is a functional block diagram of the server 12 and the PC 14. FIG. 11 is different from FIG. 3 in that multiple functions related to the generative AI chat process are added to the server 12 and the PC 14.

In the configuration illustrated in FIG. 11, the PC 14 includes an input receiving unit 121, a communication unit 122, and a display unit 123.

The input receiving unit 121 receives an input from the user on the user interface (UI) screen displayed by the display unit 123. Specifically, the input receiving unit 121 receives a selection of a combination of the vision encoder and an LLM and input of an image and text (an example of an “input sentence”) to the chat.

The communication unit 122 communicates with the server 12. For example, the communication unit 122 transmits the input, received by the input receiving unit 121, from the user to the server 12. For example, the communication unit 122 receives screen information for displaying a UI screen from the server 12.

The display unit 123 displays a UI screen based on the screen information received by the communication unit 122.

In the configuration illustrated in FIG. 11, the server 12 includes a storage unit 131 (memory), a communication unit 132, an identifying unit 133, a response generation unit 134, and a display control unit 135.

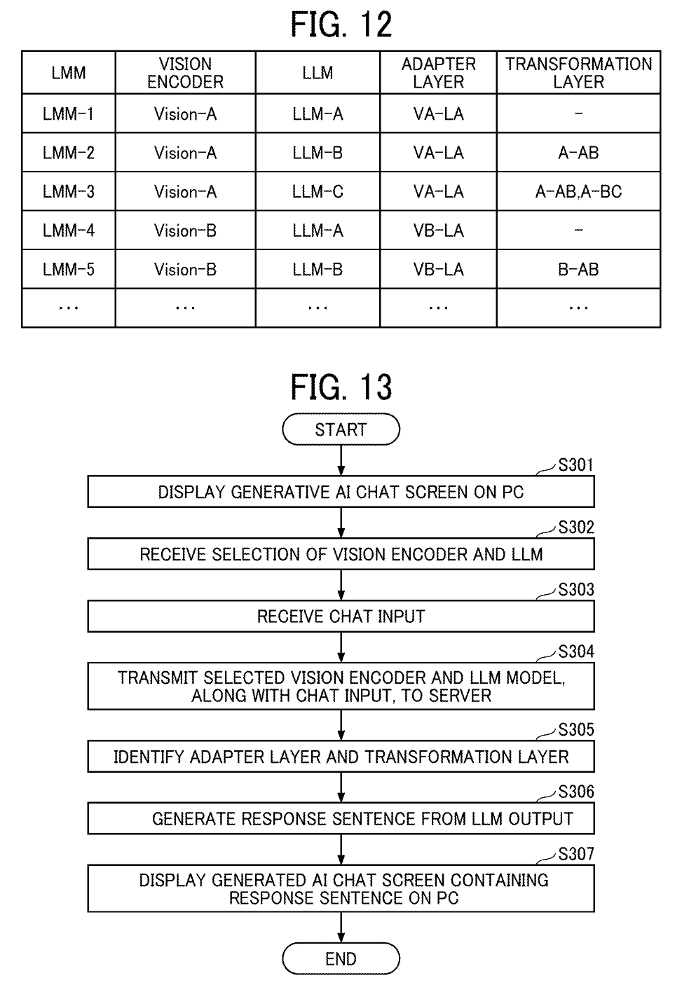

The storage unit 131 stores vision encoder, the LLM, the adapter layer, and the transformation layer in association with each other as in a data table as illustrated in FIG. 12. The storage unit 131 may store an LMM identifier to identify the combination of the vision encoder, the LLM, the adapter layer, and the transformation layer.

The communication unit 132 communicates with the PC 14. For example, the communication unit 132 receives from the PC 14 an input by the user. For example, the communication unit 132 transmits screen information for displaying a UI screen to the PC 14 under the control of the display control unit 135.

The identifying unit 133 refers to the storage unit 131 and identifies the adapter layer and the transformation layer associated with the combination of the vision encoder and the LLM selected by the user on the PC 14.

The response generation unit 134 inputs the image and the text input by the user to the LLM and generates a response sentence from the output of the LLM by using the vision encoder and the LLM selected by the user on the PC 14 as well as the adapter layer and the transformation layer identified by the identifying unit 133. The response generation unit 134 may generate a response sentence by editing and correcting the output of the LLM, or may use the output of the LLM as it is as a response sentence.

The display control unit 135 controls the screen display on the PC 14. To be specific, the display control unit 135 controls the screen display on the PC 14 by transmitting screen information for displaying the UI screen to the PC 14 via the communication unit 132. For example, the display control unit 135 displays a generative AI chat screen, which will be described later, on the PC 14.

### Data Table Stored in Storage Unit 131

FIG. 12 is a diagram illustrating a data table stored in the storage unit 131 of the server 12.

As illustrated in FIG. 12, the storage unit 131 of the server 12 stores vision encoder, an LLM, an adapter layer, and a transformation layer in association with each other by a data table.

For example, an LMM “LMM-1” has a vision encoder “vision-A,” an LLM “LLM-A,” and the vision encoder “vision-A” and the LLM “LLM-A” is connected by an adapter layer “VA-LA.”

An LMM “LMM-2” has a vision encoder “vision-A,” an LLM “LLM-B,” and the vision encoder “vision-A,” and the LLM “LLM-B.” The vision encoder “vision-A” and the LLM “LLM-B” are connected by the adapter layer VA-LA and a transformation layer A-AB.

An LMM may include multiple transformation layers, such as an LMM “LMM-3.”

### Generative AI Chat Processing by Server 12 and PC 14

FIG. 13 is a flowchart of a generative AI chat process by the server 12 and the PC 14.

In step S301, in the server 12, the display control unit 135 transmits screen information of the generative AI chat screen to the PC 14 via the communication unit 132 so that the PC 14 displays the generative AI chat screen. At this time, the communication unit 122 of the PC 14 receives the screen information of the generative AI chat screen, and the display unit 123 displays the generative AI chat screen.

In step S302, the input receiving unit 121 of the PC 14 receives selection of a vision encoder and a LLM from the user on the generative AI chat screen.

In step S303, the input receiving unit 121 receives a chat input by the user on the generative AI chat screen.

In step S304, the communication unit 122 of the PC 14 transmits the selection of the vision encoder and the LLM received in step S302, and the chat input received in step S303 to the server 12.

In step S305, in the server 12, the identifying unit 133 refers to the storage unit 131 and identifies the adapter layer and the transformation layer corresponding to the combination of the vision encoder and the LMM selected by the user.

In step S306, in the server 12, the response generation unit 134 generates a response sentence to the image and the text input by the user using the LMM having vision encoder and the LLM selected by the user as well as the adapter layer and the transformation layer identified by the identifying unit 133. The response generation unit 134 may use the output from the LMM as the response sentence as it is, or may generate the response sentence based on the output from the LMM.

In step S307, in the server 12, the display control unit 135 transmits screen information of the generative AI chat screen including the response sentence generated in step S306 to the PC 14 via the communication unit 132 so that the PC 14 displays the generative AI chat screen. At this time, the communication unit 122 of the PC 14 receives the screen information of the generative AI chat screen, and the display unit 123 displays the generative AI chat screen.

Then, the server 12 and the PC 14 end the process illustrated in FIG. 13.

### Generative AI Chat Screen

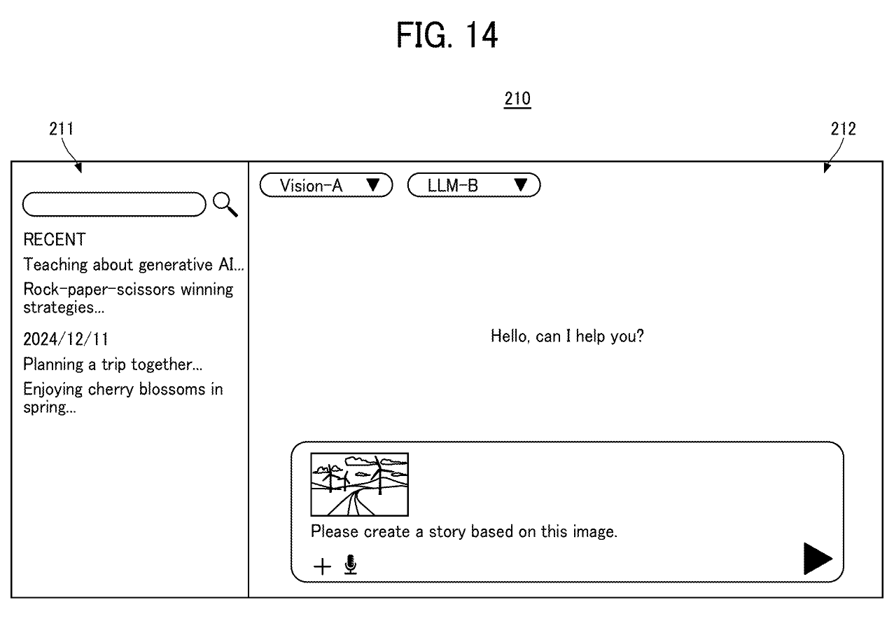

FIGS. 14 to 16 are diagrams of generative AI chat screens displayed on the PC 14.

A generative AI chat screen 210 illustrated in FIG. 14 is displayed on the PC 14 under the control of the display control unit 135 of the server 12 after an image and an input sentence are displayed by the user.

In FIG. 14, the generative AI chat screen 210 includes a display area 212 on the right, and model selection fields for selecting a vision encoder and an LMM model are displayed in an upper portion of the display area 212. The user can select a vision encoder and an LMM in the model selection fields.

In the example illustrated in FIG. 14, the image input by the user and an input sentence “Please create a story based on this image.” are displayed in the lower input field in the display area 212 in the right portion of the generative AI chat screen 210. The user can transmit the input sentence to the server 12 by pressing a triangular transmission button displayed in the input field. Further, the buttons for voice inputting and attaching a file are displayed in the input field, and the user can input an input sentence by voice and attach a file by pressing these buttons.

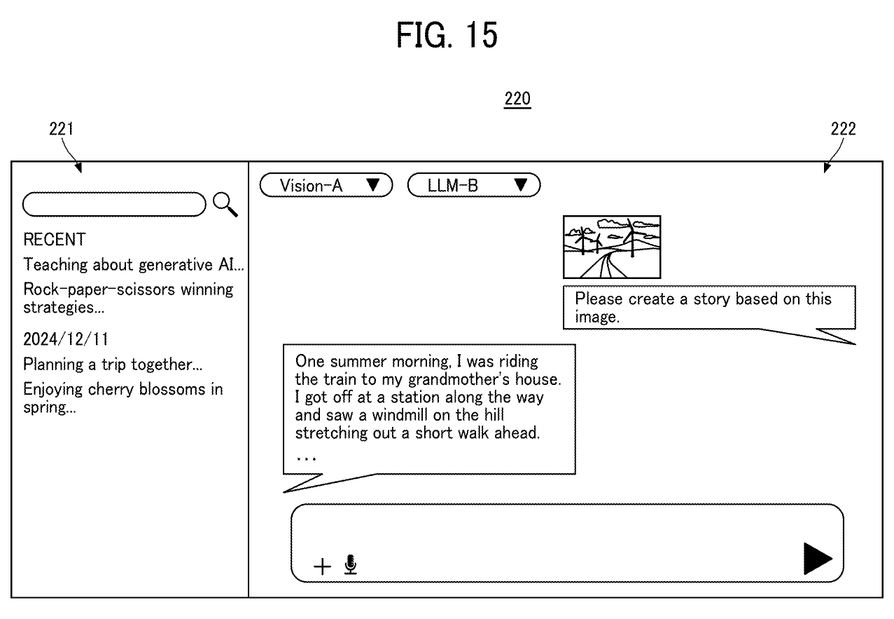

On the generative AI chat screen 220 illustrated in FIG. 15, the response sentence to the input sentence is displayed under the control of the display control unit 135 of the server 12. In the example illustrated in FIG. 15, in a display area 222 in the right portion of the generative AI chat screen 220, the input sentence input from the user and the response sentence (the story created based on the input image) to the input sentence generated by the response generation unit 134 of the server 12 are displayed in time series.

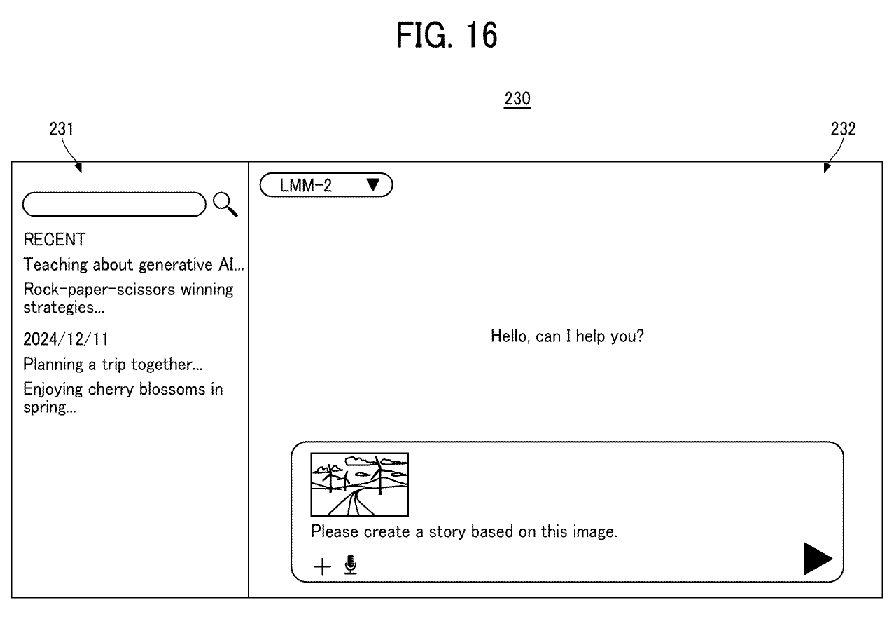

FIG. 16 illustrates a generative AI chat screen 230 according to a modification, used instead of the generative AI chat screen 210 illustrated in FIG. 14. The generative AI chat screen 230 illustrated in FIG. 16 includes a display area 232 on the right side. The display area 232 includes a model selection field for selecting an LMM in the upper part, instead of the fields for selecting a vision encoder and an LLM. The user can select an LMM in this model selection field. Even in this case, the identifying unit 133 of the server 12 can identify the adapter layer and the transformation layer corresponding to the LMM selected by the user by referring to the storage unit 131.

In the generative AI chat screens 210, 220, and 230, the history of generative AI chats is displayed in display areas 211, 221, and 231 on the left side, but the history of generative AI chats may be displayed in several groups such as “recent” and “2024/12/11” (date).

In addition, the display areas 211, 221, and 231 each include a search field to display a history of generative AI chats corresponding to a search word in response to the user’s input of the search word in the search field.

The server 12 and the PC 14 according to the present embodiment allows the user to select a combination of a vision encoder (a model for vectorizing non-text information) and an LLM in the generative AI chat process. Thus, a response sentence with higher accuracy or desired by the user can be provided to the user.

In the above description, the “input sentence” input by the user includes a text sentence and an image but is not limited to thereto. For example, the “input sentence” input by the user may include a text sentence and information other than an image (for example, voice).

An information processing system according to one aspect includes an information processing apparatus and a terminal device. The information processing apparatus includes first circuitry to transform non-text information into vectorized information using an information vectorizing model, transform the vectorized information into a first output in a first format processable by a first large-scale language model, transform the first output into a second output in a second format processable by a second large-scale language model, input the second output to the second large-scale language model; and output a response based on a processing result of the second large-scale language model. The terminal device includes second circuitry to receive a user’s selection of a combination of a vision encoder and a large-scale language model, and input of an input sentence, and display, on a display, a response sentence based on the processing result of the second large-scale language model.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

The functionality of the elements disclosed herein may be implemented using circuitry or processing circuitry which includes general purpose processors, special purpose processors, integrated circuits, application-specific integrated circuits (ASICs), field-programmable gate arrays (FPGAs), and/or combinations thereof which are configured or programmed, using one or more programs stored in one or more memories, to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a compact disc-read-only memory (CD-ROM) or DVD, and/or the memory of an FPGA or ASIC.

1. An information processing apparatus comprising circuitry configured to:
transform non-text information into vectorized information using an information vectorizing model;
transform the vectorized information into a first output in a first format processable by a first large-scale language model;
transform the first output into a second output in a second format processable by a second large-scale language model, the second format being different from the first format;
input the second output to the second large-scale language model; and
output a response based on a processing result of the second large-scale language model.

2. The information processing apparatus according to claim 1, wherein
the circuitry is configured to perform linear transformation on the first output using a transformation layer.

3. The information processing apparatus according to claim 2, wherein
the first large-scale language model includes a first text vectorizing model that vectorizes text,
the second large-scale language model includes a second text vectorizing model that vectorizes text, and
the circuitry is configured to generate the transformation layer based on a relation between a basis of a vector obtained by the first text vectorizing model and a basis of a vector obtained by the second text vectorizing model.

4. The information processing apparatus according to claim 3, wherein
the circuitry is configured to:
inputting a string to the first large-scale language model to obtain multiple first vectors;
average the multiple first vectors to generate a first word vector;
input the string to the second large-scale language model to obtain multiple second vectors;
average the multiple second vectors to generate a second word vector; and
generate the transformation layer based on the first word vector and the second word vector, and
the transformation layer linearly transforms the first word vector into the second word vector.

5. The information processing apparatus according to claim 3, further comprising a memory that stores the generated transformation layer and an adapter layer in association with a combination of a vision encoder and a large-scale language model, wherein
the circuitry is configured to:
refer to the memory to identify the transformation layer and the adapter layer corresponding to a combination of the vision encoder and the large-scale language model selected by a user; and
generate a response sentence to an input sentence received from the user, based on an output of the large-scale language model that includes the identified transformation layer and the identified adapter layer.

6. An information processing method comprising:
transforming non-text information into vectorized information using an information vectorizing model;
transforming the vectorized information into a first output in a first format processable by a first large-scale language model;
transforming the first output into a second output in a second format processable by a second large-scale language model, the second format being different from the first format;
inputting the second output to the second large-scale language model; and
outputting a response based on a processing result of the second large-scale language model.

7. A non-transitory recording medium storing a plurality of program codes which, when executed by one or more processors, causes the one or more processors to perform a method, the method comprising:
transforming non-text information into vectorized information using an information vectorizing model;
transforming the vectorized information into a first output in a first format processable by a first large-scale language model;
transforming the first output into a second output in a second format processable by a second large-scale language model, the second format being different from the first format;
inputting the second output to the second large-scale language model; and
outputting a response based on a processing result of the second large-scale language model.
